(19) United States
(12) Patent Application Publication
(10) Pub. No.: US 2016/0010212 A1
(43) Pub. Date: Jan. 14, 2016

(54) PROCESS FOR OBTAINING A SUBSTRATE EQUIPPED WITH A COATING

(71) Applicant: SAINT-GOBAIN GLASS FRANCE, Courbevoie (FR)

(72) Inventors: Brice DUBOST, Paris (FR); Emmanuel MIMOUN, Boulogne-Billancourt (FR); Matthieu BILAINE, Paris (FR)

(73) Assignee: SAINT-GOBAIN GLASS FRANCE, Courbevoie (FR)

(21) Appl. No.: 14/761,749

(22) PCT Filed: Jan. 17, 2014
(86) PCT No.: PCT/FR14/50090

§ 371 Date: Jul. 17, 2015

(30) Foreign Application Priority Data
Jan. 18, 2013 (FR) 1350453

(51) Int. Cl. C23C 16/56; C23C 16/50; C23C 16/48; C23C 16/52

(52) U.S. Cl. CPC C23C 16/56; C23C 16/52; C23C 16/50; C23C 16/483

(57) ABSTRACT

One subject of the invention is a process for obtaining a substrate (1) provided on at least one of its sides with a coating, wherein said coating is deposited on said substrate (1), then said coating is heat treated using at least one heating means (2a) opposite which the substrate (1) runs, the process being such that, prior to the heat treatment, at least one measurement of at least one property of said coating is carried out on the running substrate (1) and the conditions of the heat treatment are adapted as a function of the previously obtained measurement.

The invention relates to the heat treatment of substrates provided with coatings.

A process of rapid heat treatment of coatings using various heating means, such as burners, plasma torches, or else lasers is known from application WO 2008/096089.

The objective of the invention is to improve this type of process, by making it more flexible and even better suited to an industrial context.

For this purpose, one subject of the invention is a process for obtaining a substrate provided on at least one of its sides with a coating, wherein said coating is deposited on said substrate, then said coating is heat treated using at least one heating means opposite which the substrate runs, the process being such that, before the heat treatment, at least one measurement of at least one property of said coating is carried out on the running substrate and the conditions of the heat treatment are adapted as a function of the previously obtained measurement.

Preferably, the coating is heat treated using at least two heating means that can be controlled independently one from another and opposite which the substrate runs, each heating means treating a different zone of said coating, the process further being such that, before the heat treatment, and for each of said zones, at least one measurement of at least one property of said coating is carried out on the running substrate and the conditions of the heat treatment of each zone are adapted as a function of the measurement obtained previously for the zone in question.

Another subject of the invention is a device for the heat treatment of a coating, deposited on a substrate, comprising at least one heating means opposite which the substrate can run, at least one means for measuring at least one property of said coating, positioned upstream of the or each heating means, and means for adapting the heat treatment conditions as a function of the measurement obtained previously.

Preferably, the device comprises at least two heating means that can be controlled independently of one another and opposite which the substrate can run, each heating means being capable of treating a different zone of said coating, means for locally measuring at least one property of said coating in each of said zones, positioned upstream of the heating means, and means for adapting the heat treatment conditions of each zone as a function of the measurement obtained previously for the zone in question.

The measurement and heat treatment steps, carried out on the running substrate, are advantageously carried out in-line, that is to say on the same industrial line, within the device according to the invention.

The possibility of controlling the heat treatment as a function of the characteristics of the layer makes it possible to render the process more flexible and/or to increase the homogeneity of the coating after treatment.

Moreover, the use of several heating means each treating a portion of the coating and the possibility of controlling them individually as a function of the local characteristics of the portion of coating to be treated have a large number of advantages.

In particular, for large-sized substrates, such as for example glass panels of 6*3.3 m², the use of several heating means instead of a single one makes it possible to facilitate the design, the manufacture, the adjustment and the maintenance of the heating means and of the associated devices (for example focusing devices when the heating means are lasers or microwave sources, as will be seen in greater detail in the remainder of the text). The use of several means that are independent of one another also makes it possible to adapt the treatment to substrates of different sizes, or to zones to be treated of different sizes, for example in the latter case when only one portion of the original substrate must be used and will subsequently be cut.

The choice of independent means and the possibility of controlling them in order to adapt the heat treatment conditions as a function of the local characteristics of the layer enable it to be suitable for coatings whose homogeneity is not perfect, which is frequently the case, especially in the case of large-sized substrates, such as substrates of 6*3 m² used in the glass industry. It is indeed difficult to obtain a perfectly homogeneous coating on such a large surface. For example, in the case of depositing the coating by the magnetron sputtering process, the cathodes may wear away heterogeneously. The heterogeneity of the deposition, in particular when it results in a heterogeneity of absorption, may be amplified by the heat treatment, in particular by a laser.

The or each heating means is advantageously selected from lasers, plasma torches, microwave sources, burners and inductors.

Lasers generally consist of modules comprising one or more laser sources and also forming and redirecting optics. The lasers are preferably in the form of a line, referred to as a “laser line” in the rest of the text.

The laser sources are typically laser diodes or fiber or disk lasers. Laser diodes make it possible to economically achieve high power densities with respect to the electrical supply power for a small space requirement. The space requirement of fiber lasers is even smaller, and the linear power density obtained may be even higher, for a cost that is however greater.

The radiation resulting from the laser sources may be continuous or pulsed, preferably continuous. When the radiation is pulsed, the repetition frequency is advantageously at least 10 kHz, in particular 15 kHz and even 20 kHz so as to be compatible with the high run speeds used.

The wavelength of the radiation of the or each laser line is preferably within a range extending from 800 to 1100 nm, in particular from 800 to 1000 nm. High-power laser diodes that emit at a wavelength selected from 808 nm, 880 nm, 915 nm, 940 nm or 980 nm have proved particularly suitable.

The forming and redirecting optics preferably comprise lenses and mirrors, and are used as means for positioning, homogenizing and focusing the radiation.

The purpose of the positioning means is, where appropriate, to arrange the radiation emitted by the laser sources along a line. They preferably comprise mirrors. The purpose of the homogenization means is to superpose the spatial profiles of the laser sources in order to obtain a homogeneous linear power density along the whole of the line. The homogenization means preferably comprise lenses that enable the separation of the incident beams into secondary beams and the recombination of said secondary beams into a homogeneous line. The radiation-focusing means make it possible to focus the radiation on the coating to be treated, in the form of a line of desired length and width. The focusing means preferably comprise a convergent lens.

The or each line possesses a length and a width. The term “length” of the line is understood to mean the largest dimension of the line, measured on the surface of the coating, and the term “width” is understood to mean the dimension in a direction transverse to the direction of the largest dimension. As is customary in the field of lasers, the width w of the line corresponds to the distance (along this transverse direction) between the axis of the beam (where the intensity of the radiation is at a maximum) and the point where the intensity of the radiation is equal to 1/e² times the maximum intensity. If the longitudinal axis of the laser line is referred to as x, it is possible to define a width distribution along this axis, referred to as w(x).

The mean width of the or each laser line is preferably at least 35 micrometers, in particular within a range extending from 40 to 100 micrometers or from 40 to 70 micrometers. Throughout the present text the term “mean” is understood to mean the arithmetic mean. Over the entire length of the line, the width distribution is narrow in order to avoid any treatment heterogeneity. Thus, the difference between the largest width and the smallest width is preferably at most 10% of the value of the mean width. This number is preferably at most 5% and even 3%.

The length of the or each laser line is preferably at least 10 cm or 20 cm, in particular within a range extending from 30 to 100 cm, in particular from 30 to 75 cm, or even from 30 to 60 cm. For example, it is possible to use, for a substrate of 3.3 m in width, 11 lines having a length of 30 cm.

The forming and redirecting optics, in particular the positioning means, may be adjusted manually or with the aid of actuators that make it possible to adjust their positioning remotely. These actuators (typically piezoelectric motors or blocks) may be controlled manually and/or be adjusted automatically. In the latter case, the actuators will preferably be connected to detectors and also to a feedback loop.

At least part of the laser modules, or even all of them, is preferably arranged in a leaktight box, which is advantageously cooled, and especially ventilated, so as to ensure their heat stability.

The laser modules are preferably mounted on a rigid structure referred to as a “bridge”, based on metallic elements, typically made of aluminum. The structure preferably does not comprise a marble slab. The bridge is preferably positioned parallel to the conveying means so that the focal plane of the or each laser line remains parallel to the surface of the substrate to be treated. Preferably, the bridge comprises at least four feet, the height of which can be individually adjusted in order to ensure a parallel positioning in all circumstances. The adjustment may be provided by motors located at each foot, either manually or automatically, in connection with a distance sensor. The height of the bridge may be adapted (manually or automatically), in order to take into account the thickness of the substrate to be treated, and to thus ensure that the plane of the substrate coincides with the focal plane of the or each laser line.

The linear power density divided by the square root of the duty cycle of the laser sources is preferably at least 300 W/cm, advantageously 350 or 400 W/cm, in particular 450 W/cm, or 500 W/cm and even 550 W/cm. The linear power density divided by the square root of the duty cycle is even advantageously at least 600 W/cm, in particular 800 W/cm, or even 1000 W/cm. When the laser radiation is continuous, the duty cycle is equal to 1, so that this number corresponds to the linear power density. The linear power density is measured at the place where the or each laser line is focused on the coating. It may be measured by placing a power detector along the line, for example a calorimetric power meter, such as in particular the Beam Finder power meter from the company Coherent Inc. The power is advantageously distributed homogeneously over the entire length of the or each line. Preferably, the difference between the highest power and the lowest power is equal to less than 10% of the mean power.

The energy density provided to the coating divided by the square root of the duty cycle is preferably at least 20 J/cm², or even 30 J/cm². Here too, the duty cycle is equal to 1 when the laser radiation is continuous.

In order to improve the effectiveness of the treatment, it is preferable for at least one portion of the (main) laser radiation transmitted through the substrate and/or reflected by the coating to be redirected in the direction of said substrate in order to form at least one secondary laser radiation, which preferably impacts the substrate at the same location as the main laser radiation, advantageously with the same focus depth and the same profile. The formation of the or each secondary laser radiation advantageously uses an optical assembly comprising only optical elements selected from mirrors, prisms and lenses, in particular an optical assembly consisting of two mirrors and a lens, or of a prism and a lens. By recovering at least one portion of the main radiation lost and by redirecting it toward the substrate, the heat treatment is considerably improved thereby. The choice of using the portion of the main radiation transmitted through the substrate (“transmission” mode) or the portion of the main radiation reflected by the coating (“reflection” mode), or optionally of using both, depends on the nature of the coating and on the wavelength of the laser radiation.

When each heating means is a laser, the absorption of the coating at the wavelength of the laser is preferably at least 5%, in particular 10%. It is advantageously at most 90%, in particular 80% or 70%, or 60% or 50%, and even 40% or else 30%.

The heating means may also be burners. The burners may be external combustion burners, in the sense that the mixing of the fuel and the oxidant is carried out at the tip of the burner or in the continuation of the latter. In this case, the substrate is subjected to the action of a flame. The burners may also be internal combustion burners, in the sense that the fuel and the oxidant are mixed inside the burner: the substrate is then subjected to the action of hot gases. All intermediate cases are of course possible, in the sense that only one portion of the combustion may take place inside the burner, and the other portion outside. Certain burners, in particular aeraulic burners, i.e. burners that use air as the oxidant, have premixing chambers in which all or part of the combustion takes place. In this case, the substrate may be subjected to the action of a flame and/or hot gases. Oxy-fuel combustion burners, i.e. burners that use pure oxygen, do not generally contain a premixing chamber. The gas used for the flame treatment may be a mixture of an oxidant gas, in particular selected from air, oxygen or mixtures thereof, and of a fuel gas, in particular selected from natural gas, propane, butane, or even acetylene or hydrogen, or mixtures thereof. Oxygen is preferred as oxidant gas, in particular in combination with natural gas (methane) or propane, on the one hand because it enables higher temperatures to be achieved, consequently shortening the treatment and preventing the substrate from being heated, and on the other hand because it prevents the creation of nitrogen oxides NOₓ. To achieve the desired temperatures at the thin layer, the coated substrate is generally positioned within the visible flame, in particular in the hottest region of the flame, a portion of the visible flame then extending around the treated region.

The heating means may also be plasma torches. A plasma is an ionized gas generally obtained by subjecting what is called a “plasma gas” to excitation, such as a high DC or AC electric field (for example an electric arc). Under the action of this excitation, electrons are torn out of the atoms of the gas and the charges thus created migrate toward the oppositely charged electrodes. These charges then excite other atoms of the gas by collision, creating by an avalanche effect a homogeneous or microfilamentary discharge or else an arc. The plasmas may be “hot” plasmas (the gas is thus entirely ionized and the plasma temperature is of the order of 10⁶° C.) or “thermal” plasmas (the gas is almost entirely ionized and the plasma temperature is of the order of 10⁴° C., for example in the case of electric arcs). The plasmas contain many active species, i.e. species capable of interacting with matter, including ions, electrons or free radicals. In the case of a plasma torch, a gas is injected into an electric arc and the thermal plasma formed is blown toward the substrate to be treated. The plasma torch is commonly employed to deposit thin films on various substrates by adding precursors in powder form to the plasma. The gas injected is preferably nitrogen, air or argon, advantageously comprising a volume content of hydrogen of between 5% and 50%, in particular between 15% and 30%.

The heating means may also be microwave sources. Microwaves are electromagnetic waves, the wavelength of which is between 1 mm and 1 m, suitable for the heat treatment of dielectric coatings. The microwave sources (magnetrons) are preferably combined with radiating waveguides or cavities (single-mode or multimode). By way of example, the substrate may run under radiating waveguides positioned in a tunnel. Wave traps formed by water-cooled absorbent filters are preferably positioned upstream and downstream of the sources in order to prevent any loss of waves to the outside.

When the coating comprises an electrically conductive layer (in the case of silver for example), the heat treatment may be carried out by induction. The heating means are then inductors.

The induction heating of metal parts is a process well known for achieving high temperatures in a rapid and controlled manner within conductive solid parts (reinforcement of steels, zone melting of silicon, etc.). The main applications relate to the agri-food fields (heating of vessels, cooking of flat products on metal belts, extrusion-cooking) and to the field of metal manufacturing (melting, reheating before forming, bulk heat treatment, surface heat treatment, treatment of coatings, welding, brazing).

An AC current flowing through a coil (also called a solenoid or turn) generates within it a magnetic field oscillating at the same frequency. If an electrically conductive part is placed inside the coil (or solenoid), currents induced by the magnetic field are generated therein and heat the part by the Joule effect.

The currents appear on the surface of the part to be heated. A characteristic depth known as the skin depth may be defined, giving to a first approximation the thickness of the current layer. The skin depth of the currents depends on the nature of the metal heated and decreases when the frequency of the current increases.

In the case of heating an insulating substrate covered with a conductive layer, it is preferable to use a high frequency polarization so as to concentrate the influence of the inductor on the surface portion of the material. The frequency is preferably between 500 kHz and 5 MHz, especially between 1 MHz and 3 MHz. An inductor especially adapted for the treatment of flat surfaces is preferably employed.

The temperature to which the coating is subjected during the heat treatment is preferably at least 300° C., in particular 350° C., or even 400° C.

Preferably, the temperature of the substrate on the side opposite the coated side does not exceed 100° C., in particular 50° C. and even 30° C. during the heat treatment.

According to the invention, several heating means (in particular laser lines) are preferably used. The number of heating means (in particular the laser lines) is preferably at least 3, 4, or even 5, or else 6, or 7, or 8, and even 9, or else 10 or 11, as a function of the width of the substrates to be treated. The number of heating means is preferably between 3 and 11 (limits included), in particular between 5 and 10 (limits included).

It is preferable for the heating means to be positioned so that the entire surface of the multilayer stack can be treated. Several arrangements can be envisaged depending on the size and shape of the heating means. According to one preferred embodiment, the heating means have a linear geometry; they may for example be linear burners or inductors or else laser lines.

When the heating means have such a linear geometry, in particular when they are laser lines, each means is preferably positioned perpendicular to the run direction of the substrate, or positioned obliquely. The heating means are generally parallel to one another. The various means may treat the substrate simultaneously or in a delayed manner. By way of example, the heating means (in particular the laser lines) may be positioned in a V shape, in staggered rows or else at an angle.

The heating means may be arranged in rows perpendicular to the run direction of the substrate. The number of rows is, for example, at least 2, or even 3. Advantageously, the number of rows is not greater than 3 in order to limit the floor area of the heat treatment zone.

In order to ensure that the substrate is affected by the treatment in its entirety, it is preferable to position the heating means so that there is an overlap, that is to say that certain regions (of small size, typically of less than 10 cm, or 1 cm) are treated at least twice.

In the run direction of the substrate, the distance between two heating means treating adjacent regions is preferably such that the regions of overlap have time to return to a temperature close to ambient temperature in order to avoid damaging the coating. Typically, in the case where the heating means are laser lines, the distance between two heating means treating adjacent regions is advantageously at least three times the distance traveled by one point of the layer under the laser line.

Alternatively, the heating means may be positioned on one and the same line (in other words the number of rows is 1). In this case, and when the heating means are laser lines, it is preferable to choose a profile that makes it possible to obtain a continuous and homogeneous line at the coating.

Preferably, at least one property of the coating measured before the heat treatment is selected from the optical, electrical or dimensional properties.

The optical properties are advantageously selected from absorption, reflection, transmission and color. These properties may for example be measured by means of at least one CCD camera or photodiode coupled to at least one source of coherent or non-coherent light, and optionally to filters, prisms or arrays. These properties may be measured using a spectrophotometer.

The electrical properties are advantageously selected from resistivity, conductivity and sheet resistance. These properties may for example be measured by means of at least one contactless inductive or capacitive sensor, for example means of measuring the sheet resistance sold by Nagy Messsysteme GmbH.

The dimensional properties are advantageously selected from the position and the thickness.

These properties are measured on the substrate while running, preferably without contact with the substrate and/or the coating. Thus, the substrate runs continuously along one and the same line, firstly opposite measurement means, which locally measure the property (where appropriate in various regions of the coating), then opposite heating means.

The measurement means are advantageously distributed over one or more lines (preferably one line), as a function of their space requirement. The or each line is typically positioned perpendicular to the run direction of the substrate, or optionally obliquely.

For each region, one or more measurements can be taken, for example two, three or else four measurements.

The adjustment of the conditions of the heat treatment (where appropriate of each region) is preferably carried out automatically. The values measured may for example be processed by an algorithm that calculates the correction value to be applied. An appropriate delay is applied between the measurement and the correction, calculated as a function of the run speed and of the distance separating the measurement means from the corresponding heating means. By way of example, the algorithm may be implemented by an electronic circuit, a computer program or else an expert system.

The adjustment may also be carried out manually. It may be useful to be able to adjust the conditions of the treatment both automatically and manually. An operator may for example manually stop a heating means in order to adjust the treatment to a narrower substrate but retain an automatic adjustment for the heat sources that are still active.

The adjustment of the conditions of the heat treatment may be carried out in various ways.

Advantageously, the conditions of the heat treatment are adjusted by modifying the power delivered by the heating means. Preferably, the conditions of the heat treatment of each region are adapted by modifying the power delivered by the heating means treating said region. For example, the power (the intensity) of the or one of the laser source(s) may be modified, as a function of the measurement obtained for the property measured upstream. In the case of burners, the power of a burner may be increased by increasing the gas flow rate.

Other adjustments of the conditions of the heat treatment are possible. For example, in the case of heating means combined with focusing means (laser lines, microwave sources, etc.), the adjustment may consist of a displacement of the focusing means, enabling a displacement of the focal plane. The adjustment may also comprise a modification of at least one dimension of the laser line in order to modify its intensity at the coating, or a modification of the wavelength of the laser (in the case of tunable lasers). The adjustment of the heat treatment may also comprise a modification of the run speed of the substrate or a modification of the duty cycle in the case of pulsed laser sources.

The adjustment of the conditions of the heat treatment may comprise the shutdown of one of the heating means, or even of all the heating means. For example, if the measurement means detect the absence of coating in a given region (due in particular to a substrate size difference), the heating means (for example the laser line) opposite the region where the coating is absent may be shut down. In the event of an incident during the deposition of the coating (for example in the case of cathode reversal resulting in a coating of very high reflectivity being deposited at least locally), the laser source(s) concerned may be shut down (automatically, or manually) in order to avoid the damaging thereof.

All possible combinations between the properties measured (or the measurement means) and the heating means are of course possible, even if for reasons of conciseness they are not all disclosed in detail in the present description.

According to one particularly preferred embodiment, an optical property (in particular the absorption) of the coating is measured locally using optical sensors and the power of the laser lines is adjusted as a function of the (absorption) measurement obtained. This embodiment is particularly suitable for the case of absorbent layers treated by laser lines, the treatment according to the invention making it possible to compensate for heterogeneities of composition, of thickness, or of stoichiometry of the layer by acting on the power of the laser sources. When the absorption is locally higher in a given region, the power of the laser source treating this region is reduced, and vice versa. On the other hand, the use of a single laser line, or of several lines treating, in the same manner, the entire width of the substrate, could amplify the heterogeneities of the coating. It is clearly understood that, in this embodiment, the absorption is not necessarily measured directly by the sensors, but may for example be calculated with the aid of a transmission or reflection measurement.

The substrate may be moved using any mechanical conveying means, for example using belts, rollers or trays moving translationally. The conveying system makes it possible to control and regulate the run speed. The conveying means preferably comprises a rigid chassis and a plurality of rollers. The pitch of the rollers is advantageously within a range extending from 50 to 300 mm. The rollers probably comprise metal rings, typically made of steel, covered with plastic wrappings. The rollers are preferably mounted on bearings with reduced clearance, typically in a proportion of three rollers per bearing. In order to ensure perfect flatness of the conveying plane, the positioning of each of the rollers is advantageously adjustable. The rollers are preferably moved using pinions or chains, preferably tangential chains, driven by at least one motor.

If the substrate is made of a flexible polymeric organic material, it may be moved using a film advance system in the form of a succession of rollers. In this case, the flatness may be ensured by an appropriate choice of the distance between the rollers, taking into account the thickness of the substrate (and therefore its flexibility) and the impact that the heat treatment may have on the creation of a possible sag.

The run speed of the substrate is advantageously at least 4 m/min, in particular 5 m/min and even 6 m/min or 7 m/min, or else 8 m/min and even 9 m/min or 10 m/min. According to certain embodiments, the run speed of the substrate is at least 12 m/min or 15 m/min, in particular 20 m/min and even 25 or 30 m/min. In order to ensure a treatment that is as homogeneous as possible, the run speed of the substrate varies during the treatment by at most 10% in relative terms, in particular 2% and even 1% with respect to its nominal value.

Of course, all relative positions of the substrate and the heating means are possible provided that the surface of the substrate can be suitably irradiated. More generally, the substrate will be placed horizontally or substantially horizontally, but it may also be placed vertically, or at any possible inclination. When the substrate is placed horizontally, the heating means are generally placed so as to treat the top side of the substrate. The heating means may also treat the underside of the substrate. In this case, it is necessary for the substrate conveying system to allow the heat to pass into the zone to be treated. This is the case for example when conveying rollers are used. Since the rollers are separate entities, it is possible to place the heating means in a zone located between two successive rollers.

When both sides of the substrate are to be treated, it is possible to employ a number of heating means located on either side of the substrate, whether the latter is in a horizontal, vertical or any inclined position. These heating means may be identical or different, in particular in the case of lasers, their wavelengths may be different, especially adapted to each of the coatings to be treated. By way of example, a first coating (for example low-emissivity coating) located on a first side of the substrate may be treated by a first laser radiation that emits, for example, in the visible or the near infrared, whilst a second coating (for example a photocatalytic coating) located on the second side of said substrate may be treated by a second laser radiation, that emits for example in the infrared.

The heat treatment device according to the invention may be integrated into a layer deposition line, for example a magnetron sputtering deposition line (magnetron process) or a chemical vapor deposition (CVD) line, especially a plasma-enhanced (PECVD) line, under vacuum or at atmospheric pressure (AP-PECVD). In general, the line includes substrate handling devices, a deposition unit, optical control devices and stacking devices. For example, the substrates run on conveyor rollers, in succession past each device or each unit.

The heat treatment device according to the invention is preferably located just after the coating deposition unit, for example at the exit of the deposition unit. The coated substrate may thus be treated in line after the coating has been deposited, at the exit of the deposition unit and before the optical control devices, or after the optical control devices and before the substrate stacking devices.

The heat treatment device may also, in certain cases, be integrated into the deposition unit. For example, laser sources may be introduced into one of the chambers of a sputtering deposition unit, especially into a chamber in which the atmosphere is rarefied, especially at a pressure between 10⁻⁶ mbar and 10⁻² mbar. The heat treatment device may also be placed outside the deposition unit, but so as to treat a substrate located inside said unit. It is possible for example, in the case of the use of a laser, to provide for this purpose a window transparent to the wavelength of the radiation used, through which the laser radiation passes to treat the layer. It is thus possible to treat a layer (for example a silver layer) before the subsequent deposition of another layer in the same unit.

Whether the heat treatment device is outside the deposition unit or integrated thereinto, these “in-line” processes are preferable to a process involving off-line operations, in which it would be necessary to stack the glass substrates between the deposition step and the heat treatment.

However, processes involving off-line operations may have an advantage in cases in which the heat treatment according to the invention is carried out in a place different from that where the deposition is carried out, for example in a place where conversion of the glass takes place. The heat treatment device may therefore be integrated into lines other than the layer deposition line. For example, it may be integrated into a multiple glazing (especially double or triple glazing) manufacturing line or into a laminated glazing manufacturing line, or else into a bent and/or tempered glazing manufacturing line. Laminated or bent or tempered glazing may be used both as building glazing or motor vehicle glazing. In these various cases, the heat treatment according to the invention is preferably carried out before the multiple glazing or laminated glazing is produced. The heat treatment may however be carried out after the double glazing or laminated glazing is produced.

When the heating means are laser sources, the heat treatment device is preferably positioned in a closed chamber that makes it possible to protect people by preventing any contact with the laser radiation and to prevent any pollution, in particular of the substrate, optics, or treatment zone.

The coating may be deposited on the substrate by any type of process, in particular processes generating predominantly amorphous or nanocrystalline layers, such as the sputtering, especially magnetron sputtering, process, the plasma-enhanced chemical vapor deposition (PECVD) process, the vacuum evaporation process or the sol-gel process.

Preferably, the coating is deposited by sputtering, especially magnetron sputtering (magnetron process).

For greater simplicity, the heat treatment of the coating preferably takes place in air and/or at atmospheric pressure. However, it is possible for the heat treatment of the multilayer stack to be carried out within the actual vacuum deposition chamber, for example before a subsequent deposition.

The substrate is preferably made of glass, of glass-ceramic or of a polymeric organic material. It is preferably transparent, colorless (it is then a clear or extra-clear glass) or colored, for example blue, gray, green or bronze. The glass is preferably of soda-lime-silica type, but it may also be glass of borosilicate or alumino-borosilicate type. The preferred polymeric organic materials are polycarbonate, polymethyl methacrylate, polyethylene terephthalate (PET), polyethylene naphthalate (PEN), or else fluoropolymers such as ethylene tetrafluoroethylene (ETFE). The substrate advantageously has at least one dimension greater than or equal to 1 m, or 2 m and even 3 m. The thickness of the substrate generally varies between 0.5 mm and 19 mm, preferably between 0.7 and 9 mm, in particular between 2 and 8 mm, or between 4 and 6 mm. The substrate may be flat or curved, or even flexible.

The glass substrate is preferably of float glass type, that is to say capable of having been obtained by a process that consists in pouring the molten glass onto a bath of molten tin (“float” bath). In this case, the coating to be treated may equally be deposited on the “tin” side as on the “atmosphere” side of the substrate. The terms “atmosphere” and “tin” sides are understood to mean the sides of the substrate that have respectively been in contact with the atmosphere prevailing in the float bath and in contact with the molten tin. The tin side contains a small superficial amount of tin that has diffused into the structure of the glass. The glass substrate may also be obtained by rolling between two rolls, a technique that makes it possible in particular to imprint patterns onto the surface of the glass.

The heat treatment is preferably intended to improve the crystallization of the coating, in particular by an increase in the size of the crystals and/or in the amount of crystalline phase. The heat treatment may also be intended to oxidize a layer of a metal or of a metal oxide that is sub-stoichiometric in oxygen, optionally by promoting the growth of a particular crystalline phase.

Preferably, the heat treatment step does not perform melting, even partial melting, of the coating. In the cases where the treatment is intended to improve the crystallization of the coating, the heat treatment makes it possible to provide sufficient energy to promote the crystallization of the coating by a physicochemical mechanism of crystalline growth around nuclei already present in the coating, while remaining in the solid phase. This treatment does not use a mechanism of crystallization by cooling starting from a molten material, on the one hand because that would require extremely high temperatures and, on the other hand, because that would be capable of modifying the thicknesses or the refractive indices of the coating, and therefore its properties, by modifying, for example, its optical appearance.

The treated coating the coating preferably comprises at least one thin layer of a metal, an oxide, a nitride, a carbide, an oxynitride or any mixture thereof. It preferably comprises a thin layer selected from metal layers (in particular based on or consisting of silver or molybdenum), titanium oxide layers and transparent electrically conductive layers.

The transparent electrically conductive layers are typically based on mixed indium tin oxides (referred to as “ITOs”), based on mixed indium zinc oxides (referred to as “IZOs”), based on gallium-doped or aluminum-doped zinc oxide, based on niobium-doped titanium oxide, based on cadmium or zinc stannate, or based on tin oxide doped with fluorine and/or with antimony. These various layers have the distinctive feature of being layers that are transparent and nevertheless conductive or semiconductive, and are used in many systems where these two properties are necessary: liquid crystal displays (LCDs), solar or photovoltaic collectors, electrochromic or electroluminescent devices (in particular LEDs, OLEDs), etc. Their thickness, generally driven by the desired sheet resistance, is typically between 50 and 1000 nm, limits included.

The thin metallic layers, for example based on metallic silver, but also based on metallic molybdenum or metallic niobium, have electrical conduction and infrared radiation reflection properties, hence their use in solar-control glazing, in particular solar-protection glazing (with the aim of reducing the amount of incoming solar energy) or low-emissivity glazing (with the aim of reducing the amount of energy dissipated to the outside of a building or a vehicle). Their physical thickness is typically between 4 and 20 nm (limits included). The low-emissivity multilayer stacks may frequently comprise several silver layers, typically two or three. The or each silver layer is generally surrounded by dielectric layers that protect it from corrosion and make it possible to adjust the appearance of the coating in reflection. Molybdenum is frequently used as an electrode material for photovoltaic cells based on CuInₓGa₁₋ₓSe₂, where x varies from 0 to 1. The treatment according to the invention makes it possible to reduce its resistivity. Other metals may be treated according to the invention, such as for example titanium, with the aim in particular of oxidizing it and obtaining a photocatalytic titanium oxide layer.

When the coating to be treated is a low-emissivity multilayer stack, it preferably comprises, starting from the substrate, a first coating comprising at least a first dielectric layer, at least a silver layer, optionally an overblocker layer and a second coating comprising at least a second dielectric layer.

Preferably, the physical thickness of the or each silver layer is between 6 and 20 nm.

The overblocker layer is intended to protect the silver layer during the deposition of a subsequent layer (for example if the latter is deposited in an oxidizing or nitriding atmosphere) and during an optional heat treatment of tempering or bending type.

The silver layer may also be deposited on and in contact with an underblocker layer. The multilayer stack may therefore comprise an overblocker layer and/or an underblocker layer flanking the or each silver layer.

Blocker (underblocker and/or overblocker) layers are generally based on a metal selected from nickel, chromium, titanium, niobium or an alloy of these various metals. Mention may in particular be made of nickel-titanium alloys (especially those containing about 50% of each metal by weight) and nickel-chromium alloys (especially those containing 80% nickel by weight and 20% chromium by weight). The overblocker layer may also consist of several superposed layers, for example, on moving away from the substrate, a titanium layer and then a nickel alloy (especially a nickel-chromium alloy) layer, or vice versa. The various metals or alloys cited may also be partially oxidized, and may especially be substoichiometric in oxygen (for example TiOₓ or NiCrOₓ).

These blocker (underblocker and/or overblocker) layers are very thin, normally having a thickness of less than 1 nm, so as not to affect the light transmission of the multilayer stack, and can be partially oxidized during the heat treatment according to the invention. In general, the blocker layers are sacrificial layers capable of capturing oxygen coming from the atmosphere or from the substrate, thus preventing the silver layer from oxidizing.

The first and/or the second dielectric layer is typically an oxide (especially tin oxide), or preferably a nitride, especially silicon nitride (in particular in the case of the second dielectric layer, the one furthest away from the substrate). In general, the silicon nitride may be doped, for example with aluminum or boron, so as to make it easier to deposit it by sputtering techniques. The degree of doping (corresponding to the atomic percentage relative to the amount of silicon) generally does not exceed 2%. The function of these dielectric layers is to protect the silver layer from chemical or mechanical attack and they also influence the optical properties, especially in reflection, of the multilayer stack, through interference phenomena.

The first coating may comprise one dielectric layer or a plurality of, typically 2 to 4, dielectric layers. The second coating may comprise one dielectric layer or a plurality of, typically 2 to 3, dielectric layers. These dielectric layers are preferably made of a material selected from silicon nitride, titanium oxide, tin oxide and zinc oxide, or any of their mixtures or solid solutions, for example a tin zinc oxide, or a titanium zinc oxide. The physical thickness of the dielectric layer, or the overall physical thickness of all the dielectric layers, whether in the first coating or in the second coating, is preferably between 15 and 60 nm, especially between 20 and 50 nm.

The first coating preferably comprises, immediately beneath the silver layer or beneath the optional underblocker layer, a wetting layer, the function of which is to increase the wetting and bonding of the silver layer. Zinc oxide, especially when doped with aluminum, has proved to be particularly advantageous in this regard.

The first coating may also contain, directly beneath the wetting layer, a smoothing layer, which is a partially or completely amorphous mixed oxide (and therefore one having a very low roughness), the function of which is to promote growth of the wetting layer in a preferential crystallographic orientation, thereby promoting silver crystallization through epitaxial phenomena. The smoothing layer is preferably composed of a mixed oxide of at least two metals selected from Sn, Zn, In, Ga and Sb. A preferred oxide is antimony-doped indium tin oxide.

In the first coating, the wetting layer or the optional smoothing layer is preferably deposited directly on the first dielectric layer. The first dielectric layer is preferably deposited directly on the substrate. For optimally adapting the optical properties (especially the appearance in reflection) of the multilayer stack, the first dielectric layer may as an alternative be deposited on another oxide or nitride layer, for example a titanium oxide layer.

Within the second coating, the second dielectric layer may be deposited directly on the silver layer or preferably on an overblocker, or else on other oxide or nitride layers intended for adapting the optical properties of the multilayer stack. For example, a zinc oxide layer, especially one doped with aluminum, or a tin oxide layer, may be placed between an overblocker and the second dielectric layer, which is preferably made of silicon nitride. Zinc oxide, especially aluminum-doped zinc oxide, makes it possible to improve the adhesion between the silver and the upper layers.

Thus, the multilayer stack treated according to the invention preferably comprises at least one ZnO/Ag/ZnO succession. The zinc oxide may be doped with aluminum. An underblocker layer may be placed between the silver layer and the subjacent layer. Alternatively or cumulatively, an overblocker layer may be placed between the silver layer and the superjacent layer.

Finally, the second coating may be surmounted by an overlayer, sometimes referred to as an overcoat in the art. This last layer of the multilayer stack, which is therefore the one in contact with the ambient air, is intended to protect the multilayer stack from any mechanical attack (scratches, etc.) or chemical attack. This overcoat is generally very thin so as not to disturb the appearance in reflection of the multilayer stack (its thickness is typically between 1 and 5 nm). It is preferably based on titanium oxide or a mixed tin zinc oxide, especially one doped with antimony, deposited in substoichiometric form.

The multilayer stack may comprise one or more silver layers, especially two or three silver layers. When several silver layers are present, the general architecture presented above may be repeated. In this case, the second coating relative to a given silver layer (and therefore located above this silver layer) generally coincides with the first coating relative to the next silver layer.

The thin layers based on titanium oxide have the distinctive feature of being self-cleaning, by facilitating the degradation of organic compounds under the action of ultraviolet radiation and the removal of mineral soiling (dust) under the action of water runoff. Their physical thickness is preferably between 2 and 50 nm, in particular between 5 and 20 nm, limits included.

The various layers mentioned have the common distinctive feature of seeing some of their properties improved when they are in an at least partially crystallized state. It is generally sought to maximize the degree of crystallization of these layers (the proportion of crystallized material by weight or by volume) and the size of the crystalline grains (or the size of the coherent diffraction domains measured by X-ray diffraction methods), or even in certain cases to favor a particular crystallographic form.

In the case of titanium oxide, it is known that titanium oxide crystallized in anatase form is much more effective in terms of degradation of organic compounds than amorphous titanium oxide or titanium oxide crystallized in rutile or brookite form.

It is also known that the silver layers having a high degree of crystallization and consequently a low residual content of amorphous silver have a lower emissivity and a lower resistivity than predominantly amorphous silver layers. The electrical conductivity and the low-emissivity properties of these layers are thus improved.

Similarly, the aforementioned transparent conductive layers, especially those based on doped zinc oxide, fluorine-doped tin oxide or tin-doped indium oxide, have an even higher electrical conductivity when their degree of crystallization is high.

Preferably, when the coating is conductive, its sheet resistance is reduced by at least 10%, or 15% or even 20% by the heat treatment. Here this is a question of a relative reduction, with respect to the value of the sheet resistance before treatment.

Other coatings may be treated according to the invention. Mention may especially be made, non-limitingly, of coatings based on (or consisting of) CdTe or chalcopyrites, for example of CuInₓGa₁₋ₓSe₂ type, where x varies from 0 to 1. Mention may also be made of coatings of enamel type (for example deposited by screenprinting), or of paint or lacquer type (typically comprising an organic resin and pigments).

The coated substrates obtained according to the invention may be used in single, multiple or laminated glazing, mirrors, and glass wall coverings. If the coating is a low-emissivity multilayer stack, and in the case of multiple glazing comprising at least two glass sheets separated by a gas-filled cavity, it is preferable for the multilayer stack to be placed on the side in contact with said gas-filled cavity, especially on side 2 relative to the outside (i.e. on the side of the substrate in contact with the outside of the building which is on the opposite side to the side turned toward the outside) or on side 3 (i.e. on that side of the second substrate starting from the outside of the building turned toward the outside). If the coating is a photocatalytic layer, it is preferably placed on side 1, therefore in contact with the outside of the building.

The coated substrates obtained according to the invention may also be used in photovoltaic cells or glazing or solar panels, the coating treated according to the invention being, for example, an electrode based on ZnO: Al or ZnO:Ga in multilayer stacks based on chalcopyrites (in particular of CIGS—CuInₓGa₁₋ₓSe₂-type, x varying from 0 to 1) or based on amorphous and/or polycrystalline silicon, or else based on CdTe.

The coated substrates obtained according to the invention may also be used in display screens of the LCD (Liquid Crystal Display), OLED (Organic Light-Emitting Diode) or FED (Field Emission Display) type, the coating treated according to the invention being, for example, an electrically conductive layer of ITO. They may also be used in electrochromic glazing, the thin layer treated according to the invention being, for example, a transparent electrically conductive layer, as taught in application FR-A-2 833 107.

The invention is illustrated with the aid of the following nonlimiting figures and exemplary embodiments.

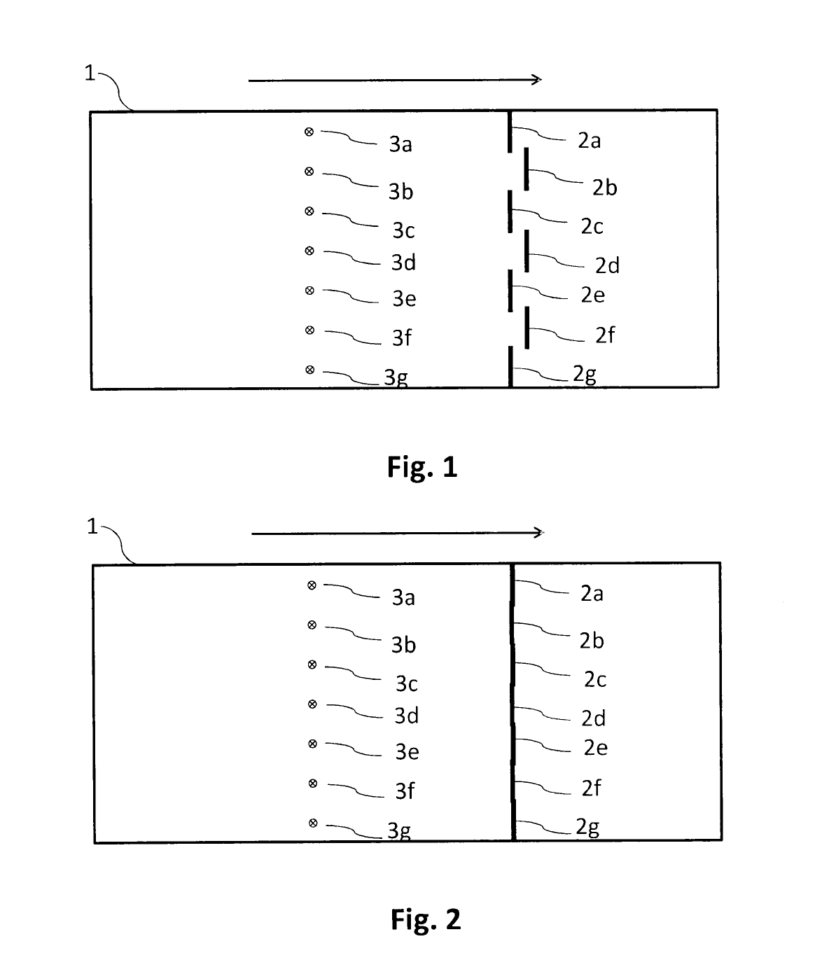

FIGS. 1 and 2 illustrate, schematically and in top view, two embodiments of the invention.

The substrate 1 equipped with its coating (not represented) is running in the direction shown by the arrow in a heat treatment device. This device comprises means 3a to 3g for locally measuring properties, which means are arranged along a line perpendicular to the run direction of the substrate 1, heating means 2a to 2g having a linear geometry, typically laser lines, here being seven in number. In the case of FIG. 1, the heating means 2a to 2g are arranged in staggered rows along two rows perpendicular to the run direction of the substrate 1. In the case of FIG. 2, the heating means 2a to 2g are arranged in one row, so as to form a single line.

The device also comprises means for adjusting the heat treatment, for example means that make it possible to adjust the power of the laser lines 2a to 2g. The measurement means 3a to 3g are for example optical sensors that make it possible to measure the local absorption of the coating.

The various points of the substrate run firstly opposite local measurement means 3a to 3g, allowing one measurement per region, here seven measurements. When each of these regions is opposite the corresponding heating means 2a to 2g, the heat treatment is adjusted as a function of the measurement made in the region. If, for example, the sensor 3c made it possible to observe a drop in absorption in a given region, the power of the laser 2c is increased when the region in question arrives opposite this laser.

In one example according to the invention, substrates of soda-lime-silica float glass sold under the name SGG Planilux by the applicant, having a dimension of 6*3.2 m² and a thickness of 4 mm, and that are coated by the multilayer stack sputtering process, were treated. This multilayer stack was of low-emissivity type comprising a thin layer of silver, the objective of the heat treatment being to reduce the emissivity of the multilayer stack owing to a better crystallization of the layer. The mean absorption of the coating (before heat treatment) was 8% at the wavelength of the lasers used.

This absorption was not identical over the entire width of the substrates, due in particular to the differences in wear at the cathodes. Thus, in the case of the substrates treated for this exemplary embodiment, the absorption was 9% along one edge and 7.5% at a third of the width starting from the opposite edge.

The heat treatment device was of the type of that from FIG. 1, except that 11 laser lines having a length of 30 cm each were used. The distance between the two rows of laser lines (measured in the run direction of the substrate) was 1 mm. These laser lines overlapped very slightly so that certain points of the coating were treated successively by two adjacent lines. However, taking into account the distance between the rows of laser lines, the regions of overlap had time to cool to ambient temperature before being subjected to treatment by the lasers of the second row.

The width of the laser lines was 40 μm and their linear power density was 450 W/cm. The laser sources were InGaAs laser diodes used in continuous radiation, at a wavelength of 980 nm. Under these conditions, for a run speed of 10 m/minute, the rise in temperature at the coating was 450° C.

Eleven sensors making it possible to measure the local absorption of the coating were positioned along a line upstream of the laser lines at around 50 cm from the latter. The sensors, sold by Optoplex, comprised lamps and photodiodes. As in the case of FIG. 1, each of the sensors made it possible to determine the absorption in a region subsequently treated by a laser line.

The adjustment of the treatment consisted here in correcting the power of the lasers as a function of the absorption measured upstream. The correction was proportional, the power of the lasers, by the current sent to the laser diodes, being reduced in proportion to the increase in absorption and vice versa. A delay was implemented between the measurement and the correction, the duration of this delay corresponding to the time needed to travel the distance between the sensors and the laser lines.

The correction was linear, in the sense that a drop of 1% in the absorption was compensated for by an increase of 1% in the power of the laser. Thus, when the absorption measured locally by one of the sensors was only 7%, the linear power density of the corresponding laser line was increased to around 500 W/cm. Conversely, at the edge where the absorption was 9%, the linear power density was reduced to 400 W/cm.

1. A process for obtaining a substrate provided on at least one of its sides with a coating, the process comprising:
depositing said coating on said substrate;
heat treating said coating with at least one heater situated opposite to running substrate,
wherein:
before the heat treating, at least one measurement of at least one property of said coating is carried out on the running substrate; and
conditions of the heat treating are adapted as a function of the at least one measurement obtained before the heat treating.

2. The process of claim 1, wherein:
said coating is heat treated with at least two heaters that can be controlled independently one from another and which are situated opposite to the running substrate;
each heater treats a different zone of said coating; and
prior to the heat treating, and for each of the different zones, at least one measurement of at least one property of said coating is carried out on the running substrate, and the conditions of the heat treating of each zone are adapted as a function of the measurement obtained before the heat treating of each zone.

3. The process of claim 1, wherein the heater is at least one selected from the group consisting of a laser, a plasma torch, a microwave source, a burner and an inductor.

4. The process of claim 3, wherein the heater is a plurality of lasers situated in the form of a line.

5. The process of claim 1, wherein the at least one property of said coating measured prior to the heat treating is selected from the group consisting of an optical property, an electrical property, and a dimensional property.

6. The process of claim 5, wherein the at least one property of said coating is at least one optical property selected from the group consisting of absorption, reflection, transmission and color.

7. The process of claim 5, wherein the at least one property of said coating is at least one electrical property selected from the group consisting of resistivity, conductivity and sheet resistance.

8. The process of claim 1, wherein the adaptation of the heat treating conditions occurs automatically.

9. The process of claim 1, wherein the heat treating conditions are adapted by modifying power delivered by the at least one heater.

10. The process of claim 1, wherein said substrate comprises a glass, a glass-ceramic or a polymeric organic material.

11. The process of claim 1, wherein said coating comprises at least one thin layer of a metal, an oxide, a nitride, a carbide, an oxynitride or any mixture thereof.

12. The process of claim 11, wherein said coating comprises at least one silver-based layer.

13. The process of claim 1, wherein the heat treating does not involve melting, or even partial melting, of said coating.

14. A device for heat treating a coating, deposited on a substrate, the device comprising:
at least one heater situated opposite to running substrate;
at least one measuring device for measuring at least one property of said coating, the at least one measuring device being positioned upstream of the at least one heater; and
an adapting device for adapting heat treating conditions as a function of measurements obtained by the at least one measuring device.

15. The device of claim 14, comprising;
at least two heaters that can be controlled independently of one another and which are situated opposite to the running substrate, wherein each heater is capable of treating a different zone of said coating,
the at least one measuring device for locally measuring at least one property of said coating in each different zone, said at least one measuring device being positioned upstream of the at least two heaters; and
the adapting device for adapting the heat treating conditions of each different zone as a function of the measurement obtained by the at least one measuring device for each different zone.
